(19) United States
(12) Patent Application Publication
(10) Pub. No.: US 2010/0209857 A1
(43) Pub. Date: Aug. 19, 2010

(54) Lithography Process for the Continuous Direct Writing of an Image

(75) Inventor: Christophe Martinez, Grenoble (FR)

Correspondence Address: LARIVIERE, GRUBMAN & PAYNE, LLP, 19 UPPER RAGSDALE DRIVE, SUITE 200, MONTEREY, CA, 93940, US

(73) Assignee: Commissariat A L'Energie Atomique, Paris (FR)

(21) Appl. No.: 12/671,488

(22) PCT Filed: Aug. 28, 2008
(86) PCT No.: PCT/EP08/61340

§ 371 Date: Jan. 29, 2010

(30) Foreign Application Priority Data
Aug. 31, 2007 (FR) 0706130

(51) Int. Cl. G03F 7/20

(52) U.S. Cl. 430/322

(57) ABSTRACT

The invention relates to photolithography techniques and more particularly to maskless photolithography techniques in which a feature is written directly onto a substrate by means of a high-energy beam, typically a laser beam.

According to the invention, the position of the beam is displaced by undergoing a continuous movement relative to the surface of the support, and the beam is switched on or off according to the feature to be written into the support. The feature is such that the smallest width of the zones to be illuminated is larger than the smallest width of the zones that have not to be illuminated. The active diameter of the illumination beam is greater than the latter. This diameter is defined according to the depth of photoresist to be irradiated and results from a compromise between the need for depthwise irradiation and the size of the features to be written. Thus, a resolution higher than that which the beam diameter theoretically allows is achieved, even for photoresists with a thickness very much greater than the size of the finest features to be produced.

### PRIORITY CLAIM

This application claims priority to PCT Patent Application Number PCT/EP2008/061340, entitled Lithography Process for the Continuous Direct Writing of an Image, filed on Aug. 28, 2008.

### FIELD OF THE INVENTION

The invention relates to photolithography techniques and more particularly to maskless photolithography techniques in which a pattern is written directly onto a substrate by means of a high-energy beam, typically a laser beam.

### BACKGROUND OF THE INVENTION

In the field of microelectronics, or more generally microtechnologies that are now tending toward nanotechnologies, the aim is to structure layers of materials with ever finer features.

Lithography is the usual technique for structuring a layer deposited on a substrate with features, the smallest width of which may at the present time be of the order of 100 nanometers. In general, lithography is practiced with a mask, the design of which is transferred in total onto a layer of photosensitive resist or photoresist: the layer is illuminated through the mask by light projection optics, here reduction optics for obtaining smaller resist features than the features of the mask. In general, the action of the light is to crosslink or cure the photoresist, most particularly when the wavelength of the light used is in the ultraviolet. The photoresist is then chemically developed so as to leave on the substrate only the irradiated zones (if the resist is a “negative” photoresist) or on the contrary only the unirradiated zones (if the photoresist is a “positive” photoresist). The photoresist remaining on the substrate serves itself as a mask for defining a localized action in the substrate that it covers, namely the action of etching a subjacent layer at points where the photoresist is absent, the action of implanting impurities at the points where the photoresist is absent, etc.

This lithography technique using a mask is advantageous because the exposure of the photoresist to the light source is instantaneous (a photoresist development step must nevertheless be provided). However, there must be a mask fabrication step, which is acceptable when the mask has to serve many times for mass fabrication runs, but is acceptable only with difficulty for very short fabrication runs (production of short series, specimens or prototypes). Moreover, this lithography technique involves exposure of the photoresist through optics, which must have a very large numeral aperture so as to guarantee good resolution. However, in that case the depth of field is very limited and it is possible to expose only very thin layers of photoresist—excessively thick photoresist layers are poorly exposed depthwise. However, thick photoresists may be necessary for carrying out deep etching of the subjacent zones not protected by the photoresist, since the latter is partly attacked by the products resulting from etching these subjacent layers, and its thickness must allow this attack to be withstood throughout the entire etching process.

The aim has therefore been to explore other lithography approaches, and more precisely maskless lithography techniques, notably:
electron beam lithography, which gives very good resolution but requires a very long fabrication time;
lithography using a spatial modulator. The mask is replaced with a matrix electrooptic light modulator which is interposed as a mask between an irradiating light source and the photoresist to be exposed. The same modulator may be configured to produce any pattern, and there is therefore no longer need for a step of fabricating a specific mask for each pattern. However, there are resolution and depth-of-field limits; and
direct writing lithography by means of a laser beam which is placed in succession above each of the photoresist zones that have to be irradiated and which is then switched on in order to carry out the irradiation. This technique provides great fineness of irradiated features but is slower the higher the desired resolution. Moreover, when the resolution is very high, the process has to be limited to small photoresist thicknesses.

### SUMMARY OF THE INVENTION

The aim of the invention is to achieve higher writing rates than in the prior art, while still benefiting from the good resolution characteristics of the direct writing technique using a laser beam, even for relatively large photoresist thicknesses, and in particular for photoresists with a thickness very much greater (by at least 10 times) than the width of the smallest features that it is desired to produce.

The invention provides a lithography process for the direct writing of an image by means of a source producing a beam of electromagnetic radiation directed onto a layer sensitive to this beam, in which the position of the beam is displaced by undergoing a continuous movement relative to the surface of the support, and the beam is switched on or off according to the feature to be written into the support, characterized in that the feature is such that the smallest width L0 of the zones to be illuminated by this beam is larger than the smallest width L of the zones that are bounded by said zones to be illuminated and that have not to be illuminated, in that the active diameter of the illumination beam is larger than the latter width, in that the thickness Δz of the sensitive film to be irradiated is at least ten times greater than the width L and in that the beam waist is between 0.8×(λΔz/2πn)^{1/2} and 1.8×(λΔz/2πn)^{1/2}, and advantageously between 0.9×(λΔz/2πn)^{1/2} and 1.1×(λΔz/2πn)^{1/2}, where λ is the wavelength of the beam, Δz is the thickness of the sensitive film to be irradiated and n is the optical index of the sensitive film. The term “beam waist” is understood to mean the usual parameter for characterizing a Gaussian beam, corresponding to the radius of the Gaussian intensity distribution measured at 1/e² of its maximum. The waist is slightly smaller than the active diameter by a factor 1/\sqrt{2 ln 2}=0.85.

The “electromagnetic beam” will in general be a light beam, notably an ultraviolet beam.

The expression “layer sensitive to this beam” is understood to mean:
either a layer of a material which is directly sensitive to the beam and into which it is desired to write a feature using the beam. For example, a support made of a transparent material, the refractive index or the crystalline structure of which may be modified through the thermal action of the radiation beam or particle beam, the desired feature being inscribed directly into this material in the form of local variations in index or in crystalline structure;
or a layer of photoresist sensitive to the beam, deposited on a substrate, and the lithography process will firstly include steps for geometrically structuring this photoresist layer in order to establish therein a defined feature, followed by steps of transferring this (positive or negative) feature onto another layer of the substrate (present beforehand beneath the photoresist or deposited subsequently after the photoresist has been developed).

The expression “active diameter of the beam” is understood to mean the diameter of a beam cross section in which the power density provides effective action on the support (notably, to cure the photoresist over its entire depth) in order to inscribe the feature thereinto, recognizing that the power density distribution over the cross section of the laser beam is in most cases approximately a Gaussian, being higher at the center and lower at the edges of the beam. The periphery of the beam, of lower energy, therefore does not form part of this active diameter.

A simplified value that may be taken as the active diameter is the mid-height width of the Gaussian curve representing the power density distribution along a diameter of the beam cross section.

The feature to be inscribed into the sensitive layer is here a feature with a high aspect ratio (greater than 10 and preferably greater than 30 or even 40). The aspect ratio considered here is the ratio of the thickness of the sensitive layer to be irradiated (for example the thickness of the photoresist deposited) to the width of the smallest features not irradiated but it is desired to produce.

According to the invention, the continuous displacement of the beam exposes the support over a width greater than the smallest features to be produced. The smallest features are photoresist features that have not to be irradiated—these are not the photoresist features that have to be irradiated. Unirradiated photoresist zones of smaller width than the beam are preserved simply by interrupting the irradiation by the beam for a sufficiently short time during its passage over the zones. Such unirradiated zones are also maintained by making the beam pass along two neighboring paths separated by a distance smaller than the active diameter of the beam, this distance defining an unirradiated photoresist feature.

In other words, the process according to the invention consists in outlining the smallest features by irradiating the photoresist all around these smallest features with a beam width smaller than these smallest features. However, the beam is given a width that takes into account the large photoresist thickness and which is defined by a formula involving this thickness.

A structure is thus established in which the finest details are smaller than the active diameter of the illumination beam; despite the existence of a very much higher aspect ratio of the features than in the prior art, abeam with an active diameter at most equal to the smallest width of the features to be produced is used, independently of the fact that this smallest width forms part of the features to be irradiated or of the features not to be irradiated.

The relative movement of the beam with respect to the support will preferably be a helical or spiral movement, depending on the nature of the support and depending on the type of features to be written. However, this may also be a zig-zagging movement or a row-by-row scanning movement.

The invention functions with positive or negative photoresists, depending on whether the smallest features remaining after the photoresist has been developed, which are smaller than the width of the beam, are islands of photoresist (islands of unirradiated photoresist bounded by the removal of the irradiated photoresist) or openings in the photoresist (openings formed by removal of unirradiated photoresist).

The time for writing onto the entire support is shorter the larger the diameter of the irradiating beam, but the diameter is chosen according to the thickness of the photoresist and not the rate to be obtained.

The scanning pitch of the beam will preferably be equal to (D+L)/k, where D is the active diameter, L is the smallest width of the zones that have not to be illuminated and k as an integer greater than 1 and preferably equal to 3 or 4.

The support will usually be in the form of a flat disk rotating about an axis perpendicular to its surface. The beam then moves translationally, directed from the periphery toward the axis (or in the opposite direction), producing a spiral scan over the surface of the disk. The rotation speed of the disk will be higher the closer the beam is to the axis, so as to keep the linear speed of displacement of the beam relative to the support constant.

In another embodiment, the support may be a circular cylinder rotating at a constant speed about the axis of the cylinder, and the beam moves translationally at a generally constant speed parallel to this axis.

### BRIEF DESCRIPTION OF THE DRAWINGS

Other characteristics and advantages of the invention will become apparent on reading the following detailed description, given with reference to the appended drawings in which:

FIG. 1 shows schematically an example of the desired structuring of the photoresist covering a substrate;

FIG. 2 shows the principle of direct writing using a laser beam scanning the surface of the substrate;

FIG. 3 shows the successive structuring steps in the case of a positive photoresist (3a to 3d) and a negative photoresist (3e);

FIG. 4 shows the molding replication steps after the successive steps of structuring a negative photoresist;

FIG. 5 shows the process carried out in the case of a continuously rotating flat support;

FIG. 6 shows the division of the support into 20 square cells;

FIG. 7 shows the process carried out in the case of a continuously rotating cylindrical support;

FIG. 8 shows the construction of the laser beam at the focal point in the photoresist;

FIG. 9 shows the formation of a Tee-shaped feature having a transverse branch and a longitudinal branch with a beam of active diameter D and a pitch p between scanning tracks of the beam; and

FIG. 10 shows the crenellated appearance of part of the feature when the latter is oblique to the scanning direction of the beam.

### DESCRIPTION OF THE PREFERRED EMBODIMENTS

The invention will be described with regard to an example in which the feature to be written into a substrate is formed indirectly from the structuring of a layer of photoresist deposited on the substrate, the combination of the substrate and the photoresist layer forming what has been called above a “support” subjected to the exposure of a high-energy beam. However, it will be understood that in certain cases the beam could directly irradiate a substrate surface not covered with photoresist but sensitive to the action of the beam, in order for features to be written directly into said surface through the action of the beam on the material of the substrate. This is the case in particular where a laser beam locally heats a transparent material in order to impose a local modification of the crystalline structure (by passing from an amorphous structure to a crystalline structure, or vice versa) or for imposing a local modification of the optical refractive index.

In the example described below by way of illustration of the invention, the beam is an ultraviolet laser beam and the photoresist is a photoresist sensitive to exposure to this ultraviolet light. It may be seen that this photoresist may be “positive” or “negative”. In the former case, the chemical development after irradiation leaves the unirradiated photoresist zones on the substrate. In the latter case, the development leaves irradiated photoresist zones thereon.

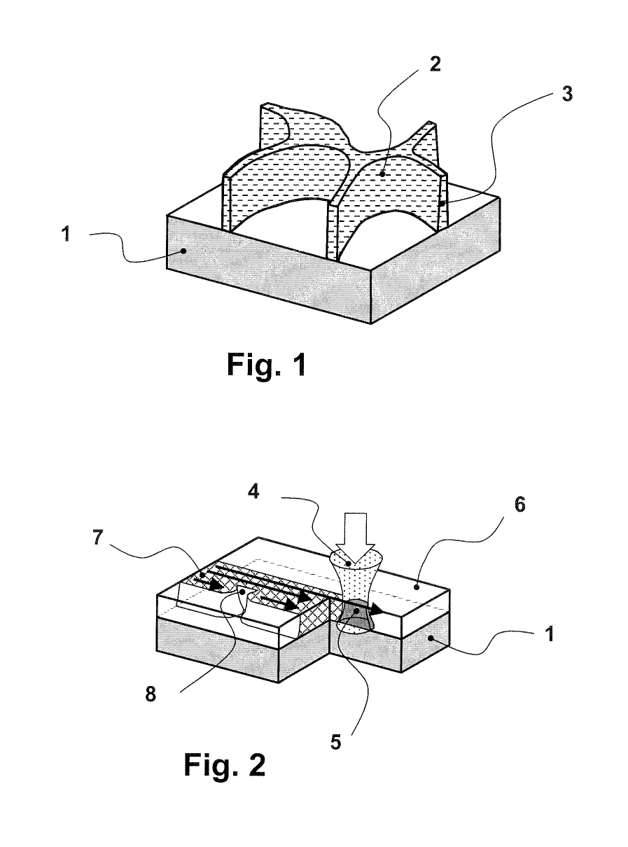

FIG. 1 shows the principle of a positive photoresist structure 2 (after development) that it is desired to produce on a substrate 1. The photoresist feature has a high aspect ratio. In this context, the aspect ratio is the ratio of the height of the structure (here, the photoresist thickness) to the smallest wall width of the feature. Typically, the height may be 10 microns and the smallest wall width may be 1 micron. However, in this structure to be produced according to the invention, the spacing between two positive photoresist walls is everywhere larger than the smallest wall width. In other words, the fineness of the feature results from the fineness of the walls and not from the fineness of the openings between walls. If the photoresist were to be a negative photoresist, the opposite would be the case—it would have openings, the smallest width of which would be smaller than the width of the smallest features of the remaining photoresist. The fineness of the feature would then result from the fineness of the openings and not from the fineness of the photoresist walls. The aspect ratio would be determined by the ratio of the negative photoresist height (for example 10 microns) to the smallest width of an opening in the photoresist (for example 1 micron).

To produce the positive photoresist structure 2 of FIG. 1, the walls are outlined according to the invention, i.e. the photoresist is exposed only at the points where walls are not to remain, during a continuous movement of the laser beam above the tracks traced over the entire surface of the substrate, the beam being switched off each time that it passes over a wall zone that has to remain after development.

FIG. 2 explains this principle. The laser beam 4 is focused onto a zone 5 of the photoresist 6, the reference 6 denoting the photoresist before the irradiation and development phases. The photoresist is irradiated in this zone 5 over its entire thickness. Passage of the laser spot focused onto the photoresist causes a depthwise modification of the photoresist, in general crosslinking or curing. The photoresist portion thus crosslinked is represented by the cross-hatched zone 7. The beam emission is locally interrupted in a zone 8 and the photoresist is not crosslinked in this zone.

The effect of the laser beam may be a direct photon effect (reaction of the photons with the structurable material) or a thermal effect (reaction due to the material under the laser spot being heated). In the case of a UV-curable photoresist, the action is mostly photonic while in the case in which the irradiation material is not a photoresist, but is the substrate directly, the action is mostly thermal, the energies involved being in this case higher.

The laser beam scans the surface of the structurable material regularly over the entire substrate, and the laser light emission is interrupted each time a zone of material has not to be irradiated.

Several irradiation strategies may be envisioned, and these will of course depend on the positive or negative nature of the photoresist used.

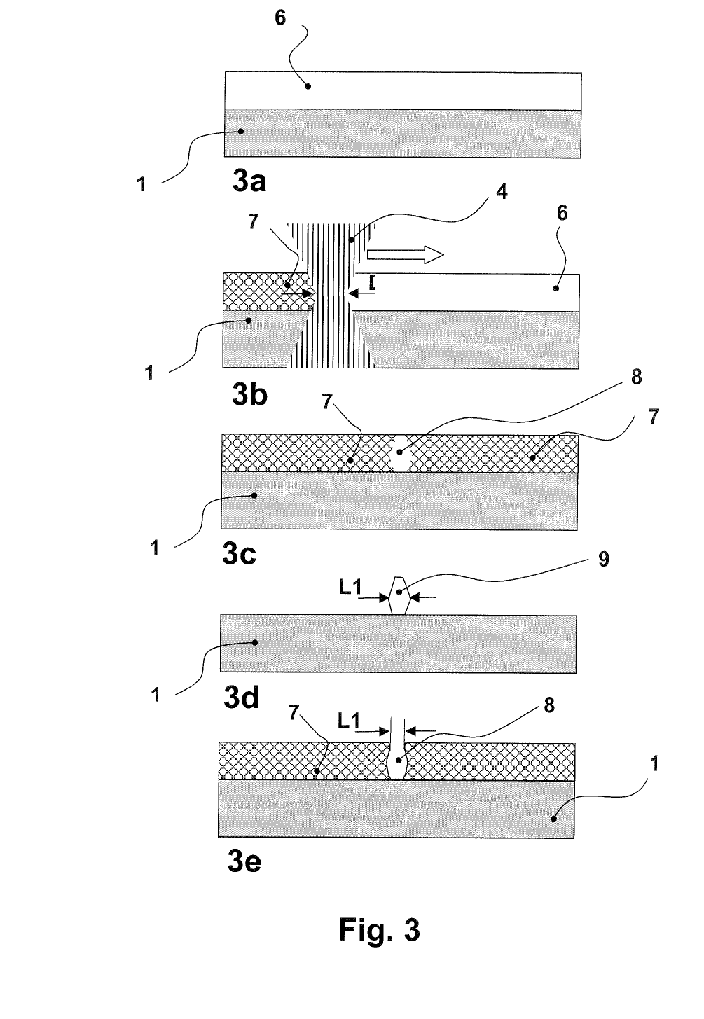

The first strategy uses a positive photoresist and the feature to be produced in the photoresist layer will be defined by the unirradiated zones that will remain on the substrate. FIGS. 3a to 3d show the various steps. FIG. 3a shows the substrate 1 covered with a uniform layer of photoresist 6. FIG. 3b shows the displacement of the laser beam 4, of active diameter D, from the left to the right above the layer, and the transformation of the photoresist in the zone 7 due to the passage of the switched-on laser beam. FIG. 3c shows that the transformed zones 7 have an interruption, denoted by 8, due to the fact that the laser beam was switched off as it was passing above the zone 8. The photoresist in the zone 8 is not cured. Finally, FIG. 3d shows the photoresist after development. The irradiated zones 7 have been removed by a selective etchant to which the unirradiated photoresist is insensitive and the irradiated photoresist is sensitive. The unirradiated zone 8 has been retained and forms a wall 9. The width L1 of this wall in the narrowest features of the structure made is smaller than the active diameter D of the laser beam. The width L1 here is linked not to the diameter D of the laser beam but to the duration of interruption of the laser beam during the relative movement between the laser source and the substrate. It will be understood that the aspect ratio may be high, but on condition that the laser beam is barely divergent throughout the thickness of the photoresist. A certain divergence has been intentionally represented so as to make this point understood, and as a result of this divergence there may be non-vertical walls of the structure, as are shown. It will be explained later how it is possible to obtain walls that are as vertical as possible even for thick photoresists.

The positive photoresist thus preserved in the zones 8 may notably serve as etching mask or as implantation mask depending on the nature of the operation that it is desired to carry out in the substrate 1. The subjacent zones will be etched or implanted at the points where the photoresist has been removed. This solution applies to the case in which the feature to be produced has very narrow zones that must not undergo implantation or etching, but not very narrow etched or implanted zones.

A second strategy consists in using a negative photoresist. The interruption of the laser beam over very short lengths during the relative movement of the laser beam with respect to the substrate will produce unirradiated zones which will be removed during the chemical development of the photoresist. The photoresist feature after development will therefore include very narrow openings, for example making it possible to carry out very narrow etching or very narrow implantation in the subjacent substrate. This is for example the case shown in FIG. 3e. The steps are the same as in FIGS. 3a, 3b and 3c, but the photoresist is negative and the irradiated portions remain after development. This solution is suitable in the case in which the narrowest zones are only zones that have to undergo implantation or etching, but not zones that have to be protected from the implantation or the etching.

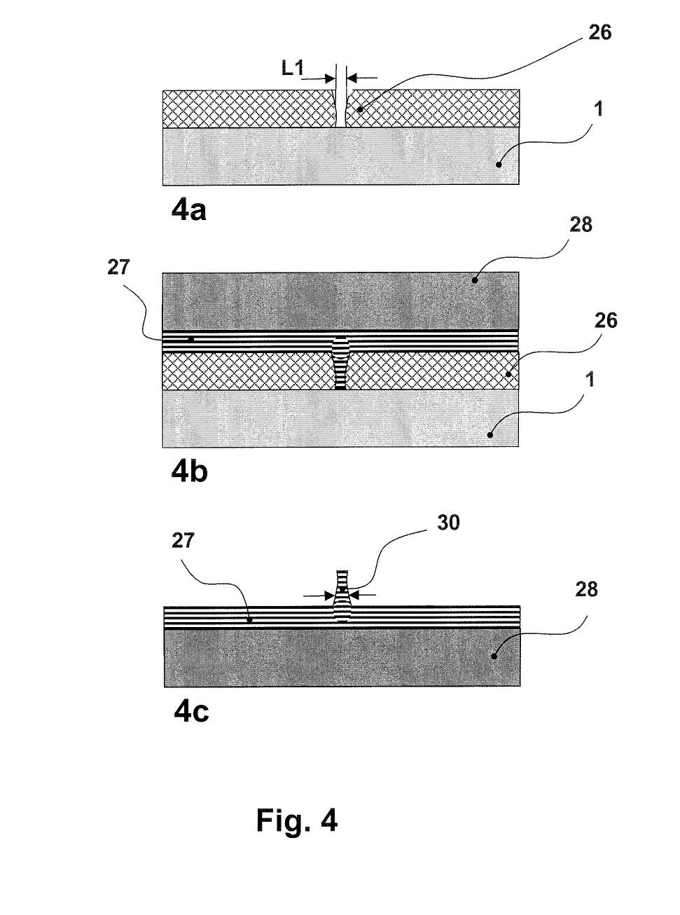

FIG. 4 shows, by way of indication illustrating the many options of the invention, another way of using a negative photoresist configured with very narrow openings of width L1 as in FIG. 3e. In this example shown in FIG. 4, a photoresist feature with very narrow openings is firstly formed, and then this feature with very narrow openings is transformed into a complementary feature with very narrow walls.

FIG. 4a shows the photoresist layer 26 after irradiation and development, with an opening of width L1 (the prior steps, analogous to FIGS. 3a, 3b and 3c but with a negative photoresist, have not been shown). FIG. 4b shows a feature transfer layer 27, which fills all the openings of the photoresist feature 26. This layer 27 may be deposited and then optionally planarized so as to bond a transfer substrate 28 thereto. The layer 27 may also be injected in liquid form in a process of the molding replication type. In FIG. 4c, both the substrate 1 and the photoresist 26 have been removed by mechanical and/or chemical action, and what remains on the transfer substrate 28 is a layer 27 having a feature which is the complement of the feature of the photoresist 26. Thus, the layer 27 is provided with a projecting wall 30 of width L1 that corresponds to the complement of the opening of width L1 left in the photoresist 26.

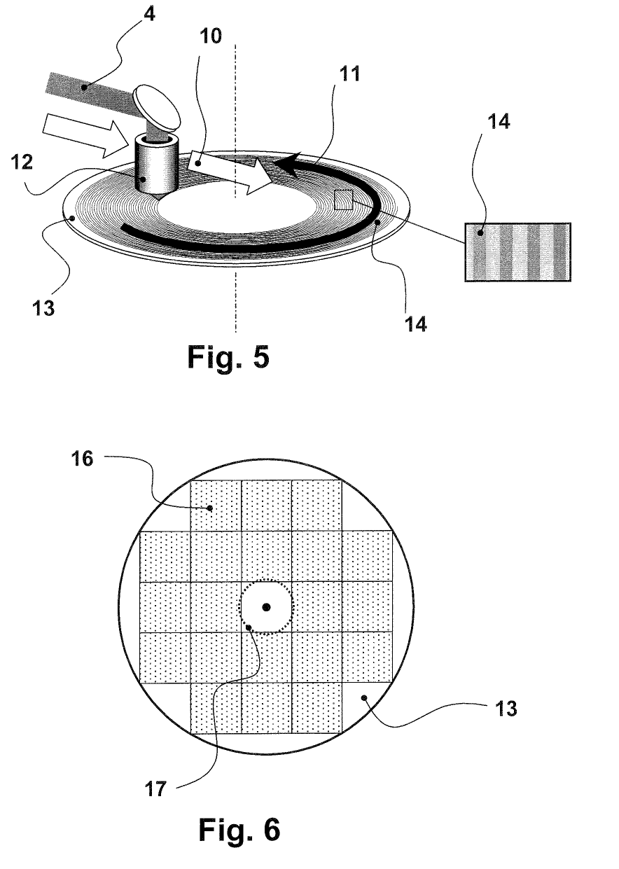

FIG. 5 shows the application of this process to a flat circular support 13 on which it is desired to etch information aligned along a spiral track 14 (or circular and concentric tracks). The focusing optics 12 of a laser source emitting abeam 4 is placed above the support 13 and the relative movement between the optics and the support is a spiral movement: the support rotates (arrow 11) about a vertical axis, and the laser source moves (arrow 10) perpendicular to the rotation axis of the support and in the direction of this axis (approaching from the periphery towards the axis or moving away from the axis toward the periphery). If it is desired for the distribution pitch of the written tracks to be p, the speed of translation Vₜᵣₐₙₛ of the beam is given a value equal to pVᵣₒₜ, where Vᵣₒₜ is the rotation speed of the support.

It should be pointed out that it is preferable for the linear speed of displacement of the spot along a track to be constant, since the energy delivered for irradiating the photoresist is linked to the speed of movement for a given power of the laser beam. If the speed is not constant, the response of the photoresist to the laser beam would not be uniform.

In the case of a spiral scan of the support 13, the length of tracks for one revolution of the support decreases as abeam approaches the rotation axis. It is therefore necessary for the rotation speed of the support to increase as the laser spot approaches the rotation axis or decreases as it moves away therefrom. The central zone of the support must be sacrificed. The radius of this central zone is linked to the maximum rotation speed that can be given to the support.

If the desired linear speed for correct exposure of the photoresist is Vₗᵢₙ, and if the maximum acceptable rotation speed is Vₘₐₓᵣₒₜ, then the radius of the sacrificed zone is Rₘᵢₙ=Vₗᵢₙ/2πVₘₐₓᵣₒₜ.

If Rₘₐₓ is the maximum radius of the support, the total exposure time of the support is T1=(1/Vₗᵢₙ)π(Rₘₐₓ²−Rₘᵢₙ²)/p.

To give an example, the numerical values could be the following:

Vₘₐₓᵣₒₜ=5000 rpm, i.e. 83 revolutions per second;

Vₗᵢₙ=8 m/s;

Rₘᵢₙ=16 mm, i.e. 0.016 m;

Rₘₐₓ=100 mm, i.e. 0.100 m;

p=833 nanometers, i.e. 833×10⁻⁹ meters,

resulting in an exposure time T1 of 1 hour 17 minutes.

If the support is divided into 20 square cells (reference 16) having sides of 32 millimeters and organized in accordance with the scoring shown in FIG. 6, (a cell is omitted at the center, which defines the sacrificed zone 17), the exposure time for each cell is about 4 minutes.

If the translation speed of the beam is continuous and constant, the relative path between the laser spot and disk is a spiral path centered on the axis of the disk. If the displacement is discontinuous, stepwise at constant time intervals equal to the duration of one revolution, the path is a succession of concentric circular tracks. The translation speed may also be considered to be overall constant on average, although the displacement is discontinuous. As a consequence, whether the displacement is continuous or discontinuous, the average speed of advance of a beam perpendicular to the tracks will be considered as constant translation speed.

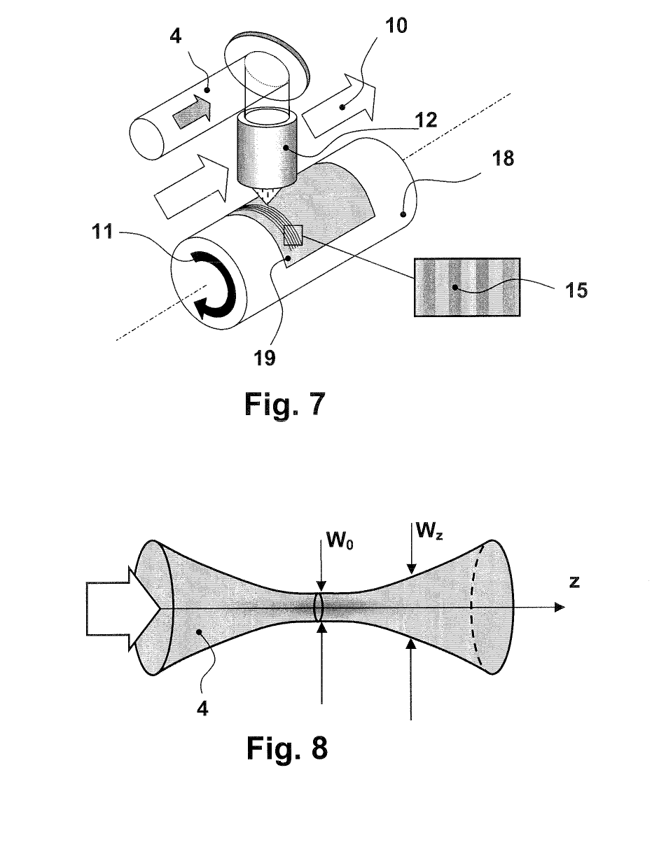

FIG. 7 shows a second embodiment of the invention, in which the support, denoted by 19, is a circular cylinder and rotates continuously (arrow 11) about its axis, and the optics 12 of the laser source moves translationally (arrow 10) parallel to the rotation axis of the cylinder. This solution is applicable in particular in the case of a support 19 formed by a flexible substrate conforming to the shape of a cylindrical drum 18 which, by rotating, rotated said substrate.

If the translation speed of the beam is continuous and constant, the relative path between the laser spot and the support is a helical path, the axis of which is the rotation axis of the drum. If the displacement is a stepwise displacement at constant intervals equal to the duration of one revolution, the path is a succession of parallel circular tracks. Here again, the translation speed of the beam, which must be considered as being constant, despite the discontinuous nature of the basement steps, is the average speed.

The advantage of the method shown in FIG. 7 is the fact that the rotation speed of the drum may remain constant during the constant-speed translational displacement of the laser source. In addition, there is no sacrificed zone. The total exposure time is T2=Lₛ/(pVᵣₒₜ) where Lₛ is the length of the substrate in the translational direction of the optics 12, Vᵣₒₜ is the constant rotation speed and p is the pitch of the helical track.

With numerical values similar to those given above, and more precisely with Vₗᵢₙ=8 m/s, a pitch of 833 nanometers and a substrate measuring about 160 mm×130 mm (the latter value, namely 130 mm, being taken parallel to the rotation axis) comprising twenty square cells with sides of 32 mm, it is possible to use a drum of about 30 millimeter radius and an exposure time of around one hour (3 minutes per cell) is found. The rotation speed is then in fact about 2,500 rpm. If the rotation speed is increased to 5,000 rpm and if a linear speed of 16 m/s rather than 8 m/s is acceptable, the time may be reduced to about 30 minutes, i.e. 1 minute 30 seconds per cell.

To implement the invention in the most effective way possible, it is necessary to determine both the most appropriate beam width D for irradiating the photoresist and the displacement pitch p of the beam in its relative movement in parallel (spiral or helical) lines, these two quantities being linked together as will be seen later.

It will be recalled that the optics for focusing the laser establishes in principle an hourglass-shaped beam, such as that shown in FIG. 8: the beam progressively converges up to a zone where it is narrowest, and then it diverges.

The optical calculation, the details of which will not be entered into here, makes it possible to show that the divergence of the beam is greater the smaller the minimum diameter of the beam, at the point where the convergence is greatest. If it is desired to expose a very deep photoresist while still ensuring that the walls are very vertical, it is therefore necessary to use a wider beam than if it is desired to expose a thinner photoresist. In the prior art, there is therefore lower resolution because of the wider write beam when the photoresist thickness is larger. The invention makes it possible to use a wider beam, and therefore not very divergent, while still maintaining very good resolution since the process involves outlining the narrowest features, which are only unirradiated features—thicker photoresists may therefore be correctly exposed.

However, if the beam is wider, it should also be pointed out that exposure precision is lost both in the width direction of the beam and in the depth direction of the irradiated photoresist, because of the Gaussian energy distribution within the beam. A more spread-out beam has an energy distribution with less sharp boundaries between the active portion and the inactive portion of the beam cross section. The crosslinking of the irradiated photoresist is in fact very dependent on the energy distribution within the beam and there are crosslinking threshold effects depending on the received illumination dose, the received dose at a point being both dependent on the distance x of the point relative to the beam axis and on the position of the point along this axis (therefore the depth of the point in the photoresist).

The use of an excessively wide beam would therefore run the risk of losing precision in the photoresist crosslinking boundary, something which could be improved by reducing the beam divergence. An active beam diameter will therefore be chosen that is not the widest possible but is an acceptable compromise.

A preferred value of the beam waist w₀ at the point of maximum convergence is defined by the following equation:

w₀=(λΔz/2πn)^{1/2},

λ is the wavelength of the laser beam, Δz is the depth of the sensitive layer that it is desired to irradiate (for example the thickness of the deposited photoresist) and n is the optical index of the sensitive layer (for example the photoresist). According to the invention, a beam waist of between 0.8 times and 1.8 times the value (λΔz/2πn)^{1/2} will be used. Preferably, according to the invention a beam waist of between 0.9 and 1.1 times the value (λΔz/2πn)^{1/2} will be used.

For example, for a photoresist depth of 20 microns, a wavelength of 500 nanometers and an optical index of 1.5, a beam waist of between 0.8 μm and 1.8 μm may be chosen and preferably one between 0.9 μm and 1.1 μm. In accordance with the practice of those skilled in the art, the waist is defined as being equal to the radius of the intensity distribution of the beam at 1/e² of the maximum level. The waist is linked to the active diameter via the factor \sqrt{2 ln 2}.

The active diameter of the beam is considered to be typically defined, for a Gaussian energy distribution within the beam, by the distance separating two diametrically opposed points for which the power density is one half of the power density on the beam axis (in other words, the active diameter is then considered, in order to simplify matters, as being the half-height width of the Gaussian power density distribution).

In all cases, the beam diameter D will be equal to or smaller than the smallest width L0 of the zones that are to be illuminated. The invention applies only to the production of structures in which the smallest width of the zones to be irradiated is larger than the smallest width of the zones that are not to be irradiated.

When continuously scanning the beam over the support, the beam has to be switched on along its path and switched off each time that an unirradiated photoresist feature has to be written transversely to the direction of relative displacement of the beam with respect to the support. In addition, parallel tracks have to be scanned in such a way that unirradiated intervals may remain between tracks, parallel to the direction of relative displacement of the beam. These two parameters will define the widths of unirradiated features and should make it possible to produce the narrowest unirradiated features provided by the design of the structure to be produced, both transversely and longitudinally.

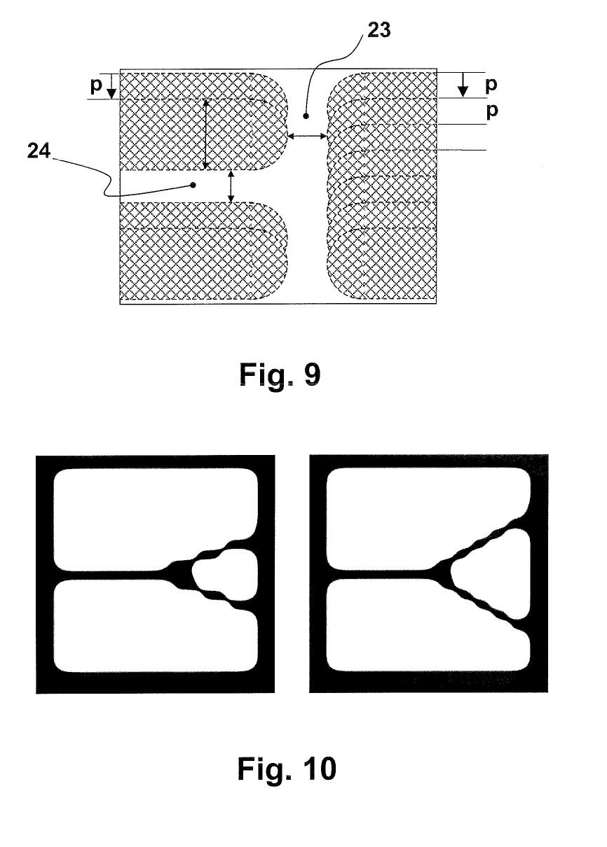

FIG. 9 shows schematically the scanning of a beam of active diameter D from the left to the right along parallel lines separated by a distance p that represents the beam displacement pitch from one track to the next. Seven beam passes are shown in the figure. The beam is switched off for a minimum time T1 during its longitudinal path in order to leave transverse unirradiated zones 23 of minimum width L1, (these being perpendicular to the path of the beam). The beam is also switched off over a time which may be greater than T1, along several consecutive tracks in order to leave unirradiated longitudinal zones 24 of minimum width L. The minimum width L is linked to the diameter D and to the pitch p of the tracks, as will be seen later. FIG. 9 therefore shows the progressive formation, on seven consecutive tracks, of an unirradiated Tee-shaped feature, the transverse branch 23 and longitudinal branch 24 of which have widths L1 and L.

The minimum width L1 in the longitudinal direction will depend on the minimum time needed to switch off the laser beam and switch it back on. For example, a beam that could be modulated at 500 MHz and moving at 8 m/s will make it possible to obtain an unirradiated feature width L1 of 22 nanometers.

The minimum width L in the transverse direction is deduced from both the pitch p and the width D of the beam according to the formula L=kp−D, k being a positive integer at least equal to 2. Specifically, assuming that a band of width D (width of the beam) is irradiated along a track, that the beam is switched off at the same point along the following k−1 tracks and that the beam is switched back on over its width D at the kth track, it may be seen that an unirradiated band of width equal to kp−D will be left. It should be noted that k cannot be equal to 1 and that p must remain smaller than D in order to allow overlap of the irradiated zones when this is necessary (irradiation over a continuous zone).

As a simplifying assumption, L may be taken to be equal to L1, i.e. the structure to be produced has very narrow unirradiated features both longitudinally and transversely. The case of oblique features will be considered later. In one example, the width of the smallest features to be produced is L=L1=0.5 microns in a 20 μm thick photoresist. The optimum waist is 927 nm, i.e. an active diameter of 1.1 μm.

The numerical values chosen for L and D mean that there is a limited choice in possible values of the pitch p to be given to the beam path. Specifically, from the formula indicated above, p=(D+L)/k.

If a high value of k is chosen, the straightness of the boundary of the transverse unirradiated zones 23 is improved, i.e. the festooning effect of the boundary due to the circular shape of the spot is reduced. However, this is to the detriment of the time for complete scanning of the surface, which may become very long if the pitch p is small, and therefore if k is high.

If on the contrary a low k value is chosen (k=2 which is the minimum value), the scanned time will be more rapid but the boundaries of the zones 23 will be festooned.

If the example shown in FIG. 9 is referred to, the beam may be considered to have a width D roughly three times the minimum width L, so that D+L is approximately equal to 4 L. Taking k equal to 4 gives a pitch p approximately equal to L, and the beam is turned off during three passes so as to constitute the unirradiated band 24 of width L=4p−D. The beam is switched back on during the fourth pass. However, it would also have been possible to take k=2, which would give a pitch p of about 2 L, or else k=3 and a pitch p of about 1.3 L, or else k=5 and a pitch of about 0.8 L.

In the numerical example in which L=0.5 microns and D=1.1 microns, a pitch p may be chosen that has the following values: p=0.8 microns (k=2); p=0.53 microns (k=3); p=0.4 microns (k=4); and p=0.32 microns (k=5). The choice of p=0.8 microns is a good compromise between speed and straightness (absence of festooning) of the boundaries oriented transversely to the movement of the beam.

FIG. 10 shows schematically the general appearance of the transverse, longitudinal and oblique boundaries will be obtained with a beam of width D and a pitch p. The slight festooning of the vertical outlines has not been shown. The highly festooned outline of the structure features that are oblique to the scanning axis of the beam is characteristic of the implementation of the process according to the invention. The two examples in FIG. 10 show this festooning for two different angles of obliquity.

What is claimed is:

1. A lithography process for the direct writing of an image by means of a source producing abeam of electromagnetic radiation directed onto a layer sensitive to this beam, in which the beam is displaced by undergoing a continuous movement relative to the layer, and the beam is switched on or off according to a feature to be written into the layer, the feature comprising at least one zone to be illuminated bounded by other zones not to be illuminated, wherein said one zone has a smallest width L0, said other zones have smallest width L smaller than L0 the illumination beam has an active diameter larger than L, the sensitive layer has a thickness at least ten times greater than L and the beam has a waist between 0.8×(λΔz/2πn)^{1/2} and 1.8×(λΔz/2πn)^{1/2}, where λ is a wavelength of the beam, Δz is the thickness of the sensitive layer and n is the optical index of the sensitive layer.

2. The lithography process as claimed in claim 1, wherein the waist of the illumination beam is between 0.9×(λΔz/2πn)^{1/2} and 1.1×(λΔz/2πn)^{1/2}.

3. The lithography process as claimed in either of claims 1 and 2, wherein the beam, by undergoing a continuous movement, scans the surface of the support along tracks distributed with a pitch p=(D+L)/k where D is the active diameter of the beam and k is an integer greater than 1.

4. Lithography process as claimed in claim 3, wherein k is equal to 2, 3 or 4.

5. The lithography process as claimed in claim 1, wherein the sensitive layer is a photosensitive resist or photoresist coated on a support and the beam is a laser beam with a wavelength at which the photoresist is sensitive, said process further comprising a positive or negative transfer of the feature onto another layer of the support.

6. The lithography process as claimed in claim 1, wherein the sensitive layer is coated on a support in the form of a flat disk rotating about an axis and the beam moves translationally from a periphery of the disk to the axis thereof, or vice versa.

7. The lithography process as claimed in claim 6, wherein the rotation speed of the support is higher the closer the beam is to the axis.

8. The lithography process as claimed in claim 1, wherein the sensitive layer is coated on a circular cylinder rotating at a constant speed about axis, and the beam moves translationally at a constant speed parallel to this axis.

9. The lithography process as claimed in claim 1, wherein the sensitive layer is part of a substrate made of a transparent material sensitive to the thermal action of the beam, for the purpose of writing a feature directly into this material.

10. The lithography process as claimed in claim 9, wherein the material is capable of undergoing a change in optical index or a change in crystalline structure under the effect of the energy supplied by the beam.
